(19) United States
(12) Patent Application Publication
(10) Pub. No.: US 2025/0292390 A1
(43) Pub. Date: Sep. 18, 2025

(54) TEST SYSTEM AND TEST METHOD

(71) Applicant: NANYA TECHNOLOGY CORPORATION, New Taipei city (TW)

(72) Inventor: Chia-Lin TSAI, New Taipei City (TW)

(21) Appl. No.: 18/607,472

(22) Filed: Mar. 17, 2024

(51) Int. Cl. G06T 7/00

(52) U.S. Cl. CPC G06T 7/0006; G06T 2207/30148

(57) ABSTRACT

A test system includes an assessment subsystem, an optical check subsystem and a process control processor. The assessment subsystem is configured to receive a test data from a wafer test apparatus, in which the test data comprises a test image of a wafer. The assessment subsystem is configured to receive an analyzed yield data of the wafer and to receive an identification data based on the test image. The process control processor is configured in response to the wafer test apparatus to perform a test operation to generate the test data, in response to the optical check subsystem to identify an image specification of probe marks in the test image and to generate the identification data, and in response to the assessment subsystem to perform an assessment operation to generate an assessment result based on the test data, the analyzed yield data, and the identification data.

### BACKGROUND

### Technical Field

The present disclosure relates to a test system and a test method.

### Description of Related Art

In integrated circuit manufacturing technology, testing is an important step for detecting defects generated during the integrated circuit fabrication process and determining the root causes of these defects. Prior to the packaging process, circuit probe testing is performed among the wafers to verify that each die meets product specifications.

With probe mark inspections being performed by operators, human errors may be introduced in the process, which affects test quality and highly time consuming. For example, test cycle time and yield is impacted. Detection of probe mark based on the customer complaints also affects the overall service quality of the manufacturer and the need for operators and engineers increase the cost of production. As a result, the time to market, scrap ratio, and product quality are impacted. In this regard, how to provide a test system and a test method that can overcome the aforementioned problem is one of the targets in the research and development in the related fields.

### SUMMARY

One aspect of the present disclosure is a test system.

According to some embodiments of the present disclosure, a test system includes an assessment subsystem, an optical check subsystem and a process control processor. The assessment subsystem is configured to receive a test data from a wafer test apparatus, in which the test data include a test image of a wafer. The assessment subsystem is configured to receive an analyzed yield data of the wafer and to receive an identification data based on the test image. The process control processor is configured in response to the wafer test apparatus to perform a test operation to generate the test data, in response to the optical check subsystem to identify an image specification of probe marks in the test image and to generate the identification data, and in response to the assessment subsystem to perform an assessment operation to generate an assessment result based on the test data, the analyzed yield data, and the identification data.

In some embodiments, the process control processor is further configured to transmit the test data, the analyzed yield data, and the identification data to the assessment subsystem in an automation mode.

In some embodiments, the process control processor is further configured to perform a verification operation on the wafer to generate the analyzed yield data.

In some embodiments, the test system further includes a database server connected to the process control processor and configured to save the test data, the analyzed yield data, and the identification data.

In some embodiments, the database server is further connected to the assessment subsystem and configured to save the assessment result.

In some embodiments, the test system further includes a recipe server connected to the process control processor and configured to save a recipe data corresponding to the wafer test apparatus.

In some embodiments, the image specification includes coordinate of the probe marks, distances between the probe marks and edges of pads of the wafer, or a combination thereof.

In some embodiments, the assessment operation includes determining whether the test data, the analyzed yield data, and the identification data meet a plurality of quality thresholds.

In some embodiments, if the test data, the analyzed yield data, and the identification data meet the quality thresholds, the assessment result indicates a pass result, and if anyone of the test data, the analyzed yield data, and the identification data fails to meet the quality thresholds, the assessment result indicates a failure result.

In some embodiments, the test data includes a distribution of probes of a probe card of the wafer test apparatus, a distance between the probes of the probe card and a surface of the wafer, a specification of the probes of the probe card, or a combination thereof.

Another aspect of the present disclosure is a test method.

According to some embodiments of the present disclosure, a test method includes performing, by a wafer test apparatus, a test operation to generate a test data, in which the test data includes a test image of a wafer. A verification operation is performed on the wafer to generate an analyzed yield data. An image specification of probe marks in the test image is identified to generate an identification data based on the test image. An assessment operation is performed, by an assessment subsystem, on the test data, the analyzed yield data, and the identification data to generate an assessment result.

In some embodiments, performing the assessment operation includes determining whether the test data, the analyzed yield data, and the identification data meet a plurality of quality thresholds.

In some embodiments, if anyone of the test data, the analyzed yield data, and the identification data fails to meet the quality thresholds, the assessment result indicates a failure result.

In some embodiments, if the test data, the analyzed yield data, and the identification data meet the quality thresholds, the assessment result indicates a pass result. The test method further includes performing a production process.

In some embodiments, performing the verification operation on the wafer to generate the analyzed yield data includes analyzing the test data to obtain a yield data and comparing the yield data and a predetermined yield data to generate the analyzed yield data.

In some embodiments, performing the test operation includes detecting a distribution of probes of a probe card, detecting a distance between the probes of the probe card and a surface of the wafer, and detecting a specification of the probes of the probe card.

In some embodiments, the test method further includes obtaining a recipe data corresponding to the wafer test apparatus.

In some embodiments, performing the test operation includes heating a probe card of the wafer test apparatus based on the recipe data and performing a clean operation on probes of the probe card based on the recipe data.

In some embodiments, the test method further includes transmitting the test data, the analyzed yield data, and the identification data to the assessment subsystem.

In the aforementioned embodiments, since the test system includes the assessment subsystem, the optical check subsystem, and the process control processor, the productivity and efficiency in testing a wafer can be enhanced. Further, manual effort and human errors can be avoided or reduced, thereby enhancing overall productivity of testing process.

It is to be understood that both the foregoing general description and the following detailed description are by examples, and are intended to provide further explanation of the disclosure as claimed.

### BRIEF DESCRIPTION OF THE DRAWINGS

The disclosure can be more fully understood by reading the following detailed description of the embodiment, with reference made to the accompanying drawings as follows:

FIG. 1 is a schematic diagram of a test system in accordance with some embodiments of the present disclosure.

FIG. 2 is a schematic diagram of a wafer test apparatus of the test system of FIG. 1 in accordance with some embodiments of the present disclosure.

FIG. 3 is a schematic diagram of test images of a wafer in accordance with some embodiments of the present disclosure.

FIG. 4 is a flow chart of a test method in accordance with some embodiments of the present disclosure.

FIG. 5 is a flow chart of a test method in accordance with some embodiments of the present disclosure.

### DETAILED DESCRIPTION

Reference will now be made in detail to the present embodiments of the disclosure, examples of which are illustrated in the accompanying drawings. Wherever possible, the same reference numbers are used in the drawings and the description to refer to the same or like parts.

It should be understood that, in this document and the following claims, when an element is referred to as being “connected” or “coupled” to another element, it can be directly connected or coupled to another element, or there may be an intervening component. In contrast, when an element is referred to as being “directly connected” or “directly coupled” to another element, there is no intervening element. In addition, “electrically connected” or “connected” may also be used to indicate that two or more elements cooperate or interact with each other.

It should be understood that, in this document and the following claims, the terms “first” and “second” are to describe the various elements. However, these elements should not be limited by these terms. These terms are used to distinguish one element from another. For example, a first element may be termed a second element. Similarly, a second element may be termed a first element without departing from the spirit and scope of the embodiments.

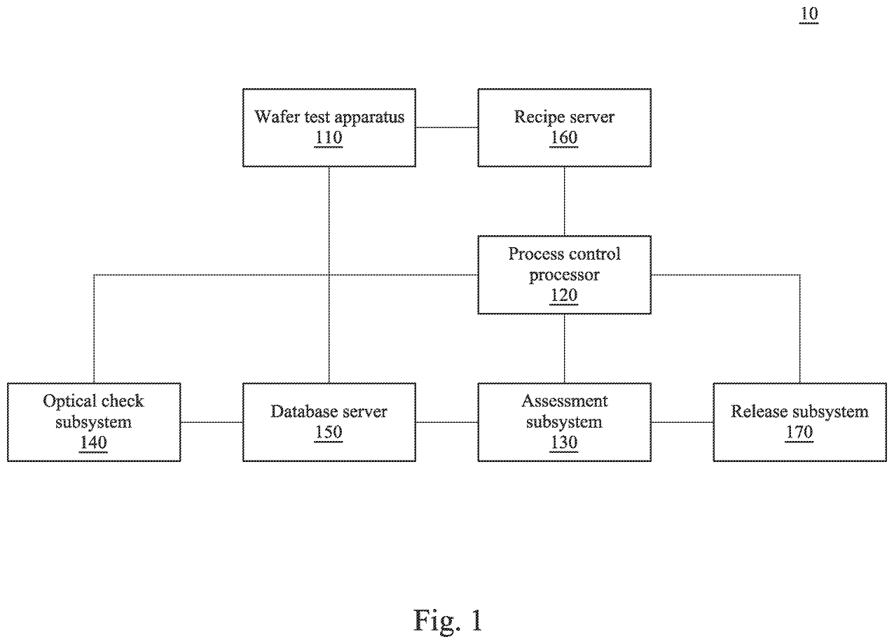

FIG. 1 is a schematic diagram of a test system 10 in accordance with some embodiments of the present disclosure. In some embodiments, the test system 10 is configured as one of test stages for a wafer (or multiple wafers) before releasing in order to assess the wafer. In some embodiments, the test system 10 is a test stage utilizing optical testing to specify surface defect on the wafers. In some embodiments, the test system 10 is an automated system to generate a test data, an analyzed yield data, and an identification data, and further to generate an assessment result based on the test data, the analyzed yield data, and the identification data before wafer (or wafer test apparatus) releasing.

Referring to FIG. 1, the test system 10 includes a wafer test apparatus 110, a process control processor 120, an assessment subsystem 130, an optical check subsystem 140, a database server 150, a recipe server 160, and a release subsystem 170. The assessment subsystem 130 is connected to the process control processor 120, the database server 150, and the release subsystem 170. The optical check subsystem 140 is connected to the process control processor 120 and the database server 150. The database server 150 is connected to the wafer test apparatus 110, the process control processor 120, the assessment subsystem 130, and the optical check subsystem 140. The recipe server 160 is connected to the wafer test apparatus 110 and the process control processor 120. The release subsystem 170 is connected to the process control processor 120 and the assessment subsystem 130.

The assessment subsystem 130 is configured to receive a test data from the wafer test apparatus 110, in which the test data includes test images of a wafer. The assessment subsystem 130 is further configured to receive an analyzed yield data of the wafer and to receive an identification data based on the test images. The process control processor 120 is configured in response to the wafer test apparatus 110 to perform a test operation to generate the test data, in response to the optical check subsystem 140 to identify an image specification of probe marks in the test images and to generate the identification data, and in response to the assessment subsystem 130 to perform an assessment operation to generate an assessment result based on the test data, the analyzed yield data, and the identification data. With the configuration of the test system 10, the productivity and efficiency in testing the wafer can be enhanced. Further, manual effort and human errors can be avoided or reduced, thereby enhancing overall productivity of testing process.

The process control processor 120 is configured to transmit the test data, the analyzed yield data, and the identification data to the assessment subsystem 130 in an automation mode. The process control processor 120 is further configured to transmit the test data, the analyzed yield data, and the identification data to the database server 150 in the automation mode. The automation mode performed by the process control processor 120 can avoid or reduce the human errors.

The process control processor 120 is configured to perform a verification operation on the wafer to generate the analyzed yield data. In some embodiments, performing the verification operation includes analyzing the test data to obtain the yield data of the wafer and comparing the yield data of the wafer and a predetermined yield data to generate the analyzed yield data. The predetermined yield data may be saved in the database server 150, the recipe server 160, or other suitable storage units. In some embodiments, the process control processor 120 is configured to create a production demand schedule. The production demand schedule may include a plurality items to be tested by using the wafer test apparatus 110. In other words, at least one of the test data, the analyzed yield data, and the identification data corresponds to the production demand schedule. The production demand schedule may be saved in the database server 150, the recipe server 160, or other suitable storage units. In some embodiments, the process control processor 120 is a central processing unit (CPU), a controller, or other analytical devices with analysis capabilities.

The assessment subsystem 130 is configured to perform the assessment operation that includes determining whether the test data, the analyzed yield data, and the identification data meet a plurality of quality thresholds. In some embodiments, if all the test data, the analyzed yield data, and the identification data meet the quality thresholds, the assessment result indicates a pass result; if anyone of the test data, the analyzed yield data, and the identification data fails to meet the quality thresholds, the assessment result indicates a failure result. The process control processor 120 is further configured to perform a subsequent operation based on the assessment result. In some embodiments, if the test data, the analyzed yield data, and the identification data meet the quality thresholds, the assessment subsystem 130 is configured to generate the assessment result indicating the pass result and the process control processor 120 is configured to control the release subsystem 170 to perform a production process. In contrast, if anyone of the test data, the analyzed yield data, and the identification data fails to meet the quality thresholds, the assessment subsystem 130 is configured to generate the assessment result indicating the failure result and the process control processor 120 is configured to perform a checking process (and not controls the release subsystem 170 to perform the production process). In some embodiments, the optical check subsystem 140 includes an automated optical inspection (AOI) apparatus. In some embodiments, the optical check subsystem 140 includes a processor and a storage unit, in which the processor is configured to capture the test image of the test data and identify the image specification of the probe marks in the test image to generate the identification data, and the storage unit is configured to save the test image and the identification data.

The database server 150 is configured to receive the test data, the analyzed yield data, and the identification data, and further configured to save the test data, the analyzed yield data, and the identification data. In some embodiments, the database server 150 is configured to receive the assessment result from the assessment subsystem 130, and further configured to save the assessment result.

In some embodiments, the assessment subsystem 130 and the database server 150 are collectively referred as a single server. That is, the single server (including a database storage unit and an assessment unit) is configured to receive the test data, the analyzed yield data, and the identification data and to generate the assessment result based on the test data, the analyzed yield data, and the identification data.

In some embodiments, the recipe server 160 is configured to save a recipe data corresponding to the wafer test apparatus 110. The recipe data may include a temperature parameter of the wafer test apparatus 110, a clean parameter of the wafer test apparatus 110, or other suitable parameters of the wafer test apparatus 110.

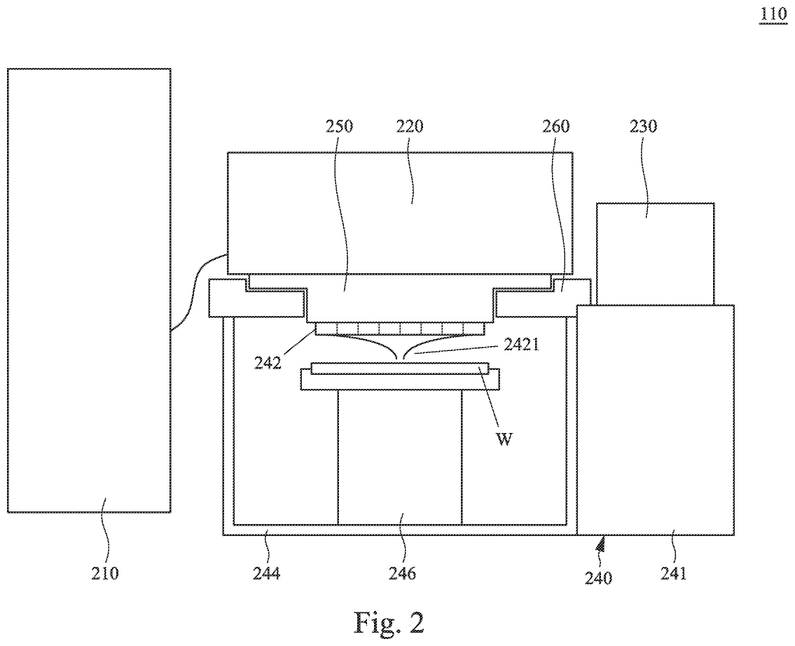

Referring to FIG. 2, FIG. 2 is a schematic diagram of the wafer test apparatus 110 of the test system 10 of FIG. 1 in accordance with some embodiments of the present disclosure. The wafer test apparatus 110 includes a tester 210, a test head 220, a loader 230, a detecting device 240, and an interface board 250. The tester 210 is configured to apply electrical signals through the test head 220 to a wafer W and to analyze the response from the wafer W. The loader 230 is configured to load or unload the wafer W. In some embodiments, the loader 230 includes a carrier that accommodates the wafer W, an opener that opens a door of the carrier, and a transfer robot that transfers the wafer W from the carrier to the detecting device 240. The detecting device 240 includes a prober 241, a probe card 242 having a plurality probes (or referred as probe needles), a chamber frame 244 defining an accommodating space for an electrical test, and a stage 246 positioned on a bottom side of the chamber frame 244 to support the wafer W. The interface board 250 is configured to provide an electrical connection between the test head 220 and the probe card 242. In some embodiments, a test operation is performed when the probe card 242 connected to the test head 220 through the interface board 250 comes into contact with the wafer W.

In some embodiments, the prober 241 of the detecting device 240 is a camera device configured to obtain the test images of the wafer W. The test images include surface images of device under tests (DUT) on the wafer W. For example, pads on the DUT of the wafer W are in contact with the probes 2421 of the probe card 242 during the test operation, and the test images include probe marks left by the probes 2421 of the probe card 242 on pads on the DUT of the wafer W. In some embodiments, the prober 241 of the detecting device 240 is a complementary metal-oxide semiconductor (CMOS) camera, a charge-coupled device (CCD) camera, a video camera, or other suitable type of camera. In some embodiments, the detecting device 240 further includes a temperature control unit for controlling a test temperature of the wafer W, a dry air supply unit for supplying dry air into the accommodating space in the chamber frame 244, and/or a flow control unit for controlling the dry air supply unit to adjust flow rate of the dry air based on the test temperature.

In some embodiments, the wafer test apparatus 110 further includes a supporting element 260 on a top side of the chamber frame 244. The supporting element 260 is configured to fix the test head 220 such that the test head 220 is located over the top side of the chamber frame 244.

In some embodiments, the wafer test apparatus 110 is used to perform the test operation and to generate the test data. The test data may include a distribution of the probes 2421 of the probe card 242, a distance between the probes 2421 of the probe card 242 and a surface of the wafer W, a specification of the probes 2421, a specification of the wafer W, or a combination thereof.

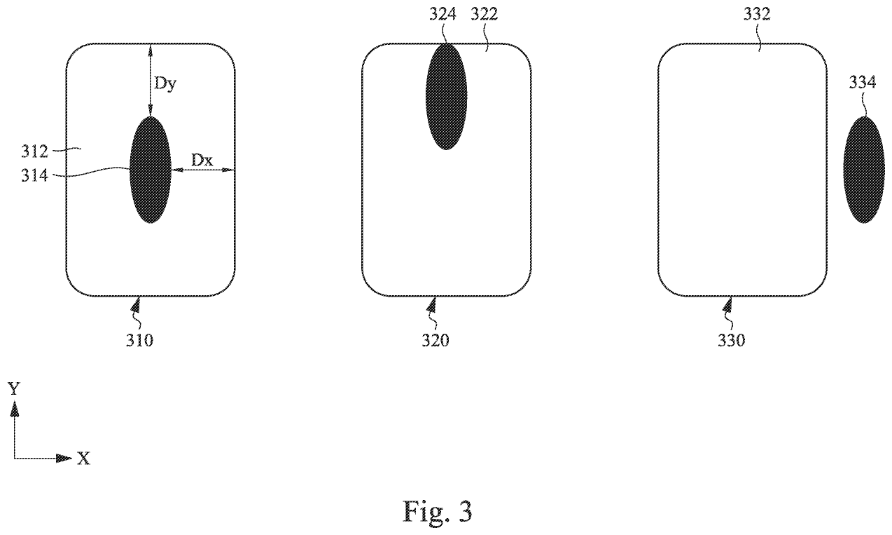

FIG. 3 is a schematic diagram of test images 310, 320, and 330 of the wafer W in accordance with some embodiments of the present disclosure. Referring to FIGS. 1-3, the test images 310, 320, and 330 may be generated from the wafer test apparatus 110 by performing the test operation. In other words, the test images 310, 320, and 330 illustrate different embodiments corresponding to portions of the wafer W of FIG. 2. In the test image 310, the wafer W includes a pad 312 and a probe mark 314 overlapping with a portion of the pad 312 and spaced apart from edges of the pad 312. The test image 310 is identified (e.g., by the optical check subsystem 140 of FIG. 1) to generate a first identification data (e.g., a first identification data indicating the probe mark overlapping with the pad and spaced apart from edges of the pad), and the first identification data is determined or assessed (e.g., by the assessment subsystem 130 of FIG. 1) to generate the assessment result indicating a pass result. In some embodiments, the probe mark 314 is spaced apart from edges of the pad 312 by a distance Dx in a X direction and a distance Dy in a Y direction. In the test image 320, the wafer W includes a pad 322, and a probe mark 324 overlapping with a portion of the pad 312 and in contact with the edges of the pad 322. The test image 320 is identified (e.g., by the optical check subsystem 140 of FIG. 1) to generate a second identification data (e.g., a second identification data indicating the probe mark overlapping with the pad and in contact with the edges of the pad), and the second identification data is determined or assessed (e.g., by the assessment subsystem 130 of FIG. 1) to generate the assessment result indicating a failure result. In the test image 330, the wafer W includes a pad 332, and a probe mark 334 not overlapping with any portion of the pad 312. The test image 330 is identified (e.g., by the optical check subsystem 140 of FIG. 1) to generate a third identification data (e.g., a third identification data indicating the probe mark not overlapping with any portion of the pad), and the third identification data is determined or assessed (e.g., by the assessment subsystem 130 of FIG. 1) to generate the assessment result indicating a failure result.

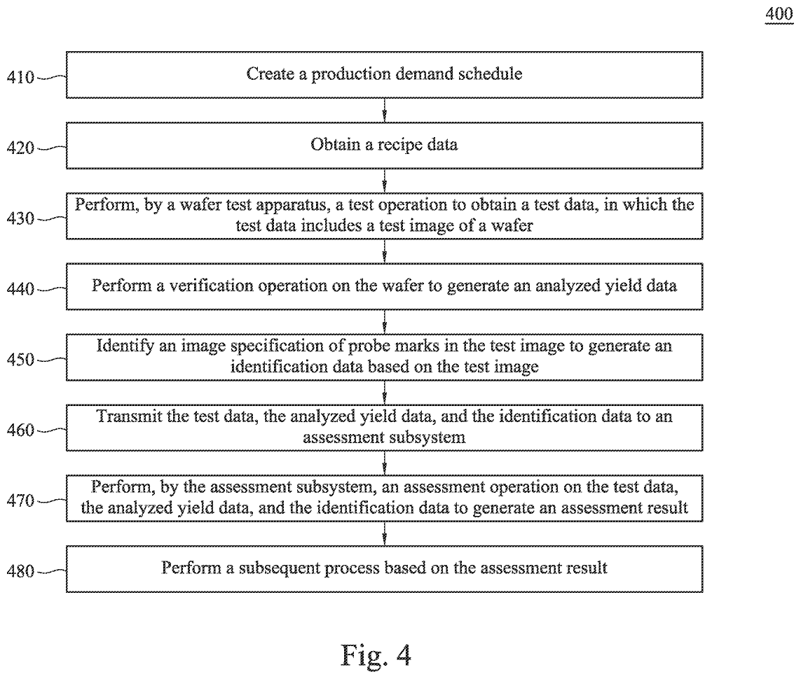

Reference is now made to FIG. 4. FIG. 4 is a flow chart of a test method 400 in accordance with some embodiments of the present disclosure. It is understood that additional steps can be provided before, during, and after the test method 400 shown by FIG. 4, and some of the steps described below can be replaced or eliminated, for additional embodiments of the test method 400. The test method 400 may include steps 410-480 that are described in more detail below with reference to FIGS. 1-4, and the test method 400 may be performed by the test system 10 as shown in FIGS. 1 and 2.

The test method 400 begins at step 410, where a production demand schedule is created. Referring to FIGS. 1 and 2, in some embodiments of the step 410, the production demand schedule is created by the process control processor 120. The production demand schedule may include a plurality items to be tested by using the wafer test apparatus 110. In some embodiments, the production demand schedule includes a plurality items to be tested and a plurality of quality thresholds corresponding to the items to be tested.

The test method 400 proceeds to step 420, where a recipe data is obtained. Referring to FIGS. 1 and 2, in some embodiments of the step 420, the recipe data is obtained from the recipe server 160. The recipe server 160 is connected to the wafer test apparatus 110 and the process control processor 120. The recipe server 160 is configured to save the recipe data corresponding to the wafer test apparatus 110. For example, the recipe data includes a temperature parameter of the wafer test apparatus 110, a clean parameter of the wafer test apparatus 110, or other suitable parameters of the wafer test apparatus 110.

The test method 400 proceeds to step 430, where a test operation is performed, by wafer test apparatus, to obtain a test data including a test image of a wafer. Referring to FIGS. 1-3, in some embodiments of the step 430, the process control processor 120 is configured in response to the wafer test apparatus 110 to perform the test operation to generate the test data. In some embodiments, the test data includes the test image of the wafer W. The test image shows an electrical specification of pads on the DUT of the wafer W. In some embodiments, the production demand schedule includes multiple items to be tested, and the test operation is performed to obtain the test data based on the items of the production demand schedule.

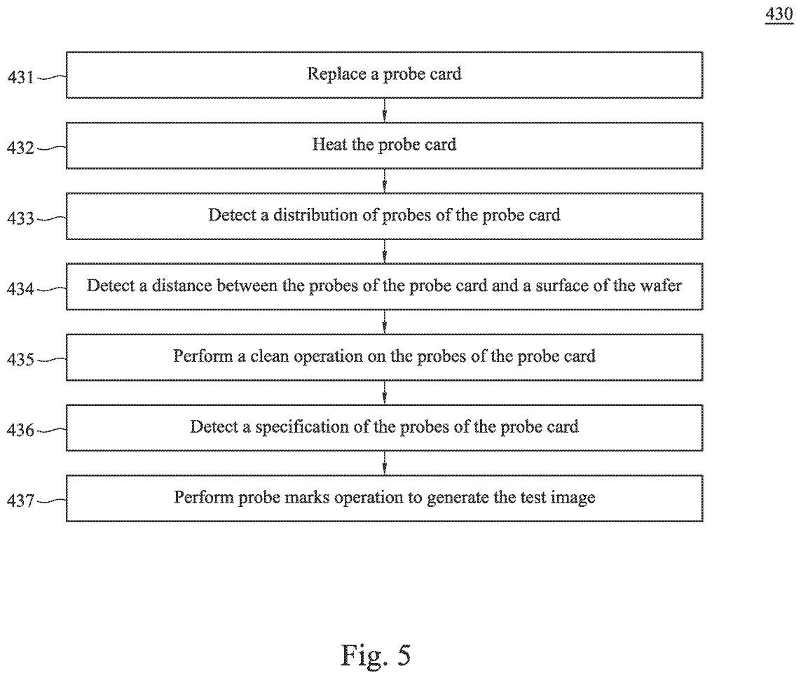

In some embodiments, the step 430 includes multiple steps 431-437 and can be performed by using the test system 10 illustrated in FIGS. 1 and 2. FIG. 5 is a flow chart of the step 430 of the test method 400 of FIG. 4 in accordance with some embodiments of the present disclosure. The flow chart shown in FIG. 5 is merely an example, and is not intended to limit the present disclosure beyond what is explicitly recited in the claims. It is understood that additional steps can be provided before, during, and after the steps shown by FIG. 5, and some of the steps described below can be replaced or eliminated, for additional embodiments of the steps of FIG. 5.

At step 431, the probe card is replaced. Referring to FIGS. 1 and 2, in some embodiments of the step 431, the probe card 242 is replaced. At step 432, the probe card is heated. Referring to FIGS. 1 and 2, in some embodiments of the step 432, the probe card 242 is heated. In some embodiments, the stage 246 of the detecting device 240 includes a heater thereon. The heater of the stage 246 of the detecting device 240 is configured to heat the probe card 242. In some embodiments, the probe card 242 of the detecting device 240 of the wafer test apparatus 110 is heated to a temperature based on the temperature parameter of the recipe data from the recipe server 160.

At step 433, a distribution of probes of the probe card is detected. Referring to FIGS. 1 and 2, in some embodiments of the step 433, a distribution of the probes 2421 of the probe card 242 is detected. In some embodiments, input electrical signals are applied by the test head 220 connected to the probe card 242 through the tester 210, and the distribution of the probes 2421 of the probe card 242 can be detected from response of the wafer W (or another test wafer) to the input electrical signals. The distribution of the probes 2421 may indicate horizontal locations of the probes 2421 and/or horizontal intervals of any adjacent two of the probes 2421.

At step 434, a distance between the probes of the probe card and a surface of the wafer is detected. Referring to FIGS. 1 and 2, in some embodiments of the step 434, a distance between the probes 2421 of the probe card 242 and a surface of the wafer W is detected. For example, the prober 241 is used to perform an optical inspection to detect the distance between the probes 2421 of the probe card 242 and the surface of the wafer W. The distance between the probes 2421 of the probe card 242 and the surface of the wafer W indicates a required distance when the probes 2421 of the probe card 242 contacts the wafer W in the probe marks operation (e.g., step 437).

At step 435, a clean operation is performed on the probes of the probe card. Referring to FIGS. 1 and 2, in some embodiments of the step 435, a clean operation is performed on the probes 2421 of the probe card 242 by using a clean wafer to clean (e.g., rub or stick) a tip portion of the probes 2421 to enhance the accuracy of performing probe marks operation (i.e., step 437). In some embodiments, the clean operation is performed on the probes 2421 of the probe card 242 based on a clean parameter of the recipe data from the recipe server 160. In some embodiments, the clean operation is performed by immersing the probes 2421 in a detergent to make the probes 2421 chemically react with the detergent. Thereafter, the probes 2421 with reactant is rinsed by clean water such that the reactant attached to the probes 2421 can be removed from the probes 2421.

At step 436, a specification of the probes of the probe card is detected. Referring to FIGS. 1 and 2, in some embodiments of the step 436, a specification of the probes 2421 of the probe card 242 is detected. For example, the prober 241 is used to perform an optical inspection to detect the specification of the probes 2421 of the probe card 242. The specification of the probes 2421 of the probe card 242 may include lengths of the probes 2421, widths of the probes 2421, sizes of the probes 2421, other suitable specification of the probes 2421, or a combination thereof.

At step 437, probe marks operation is performed to generate the test image. Referring to FIGS. 1-3, in some embodiments of the step 437, probe marks operation is performed to generate the test images. In greater details, the wafer W is loaded into the accommodating space within the chamber frame 244 and positioned on the stage 246 to face the probe card 242. Then, the probes 2421 of the probe card 242 are physically in contact with the pads of the wafer W such that the probe marks left by the probes 2421 on the pads of the wafer W. As such, the test images (e.g., test images 310, 320, or 330 of FIG. 3) including surface image of the probe marks and the pads of the wafer W are generated.

In some embodiments, as shown in FIGS. 1-4, the test data includes the distribution of the probes 2421 of the probe card 242, the distance between the probes 2421 of the probe card 242 and the surface of the wafer W, the specification of the probes 2421 of the probe card 242, the test image, the size of the wafer W, the test time, other suitable data, or a combination thereof.

The test method 400 proceeds to step 440, where a verification operation is performed on the wafer to generate an analyzed yield data. Referring to FIGS. 1 and 2, in some embodiments of the step 440, a verification operation is performed on the wafer W to generate an analyzed yield data. In some embodiments, the process control processor 120 is configured to perform the verification operation. In some embodiments, performing the verification operation includes analyzing the test data to obtain the yield data of the wafer W and comparing the yield data of the wafer W and a predetermined yield data to generate the analyzed yield data. The predetermined yield data may be obtained (or generated) with the same wafer W by using another wafer test apparatus in a similar method of the step 430. The predetermined yield data may be saved in the database server 150. Alternatively, the predetermined yield data may be saved in the recipe server 160.

The test method 400 proceeds to step 450, where an image specification of probe marks in the test image is identified to generate an identification data based on the test image. Referring to FIGS. 1-3, in some embodiments of the step 450, an image specification of probe marks in the test images (e.g., test images 310, 320, and 330) is identified to generate an identification data based on the test images. The process control processor 120 is configured to control, in response to the wafer test apparatus 110 to transmit the test images to the optical check subsystem 140, and in response to the optical check subsystem 140 to identify the image specification of probe marks in the test images and to generate the identification data in an automation mode. In some embodiments, the image specification of the probe marks in the test image is a data for inspection the quality of the tested wafers, which includes coordinate of the probe marks with respect to a reference point on the pads of the wafer W, distances between the probe marks and edges of the pads of the wafer W, locations of probe marks with respect to the edges of the pads of the wafer W, overlapping relationship between the probe marks and the pads of the wafer W, or a combination thereof. In some embodiments, the wafer test apparatus 110 is configured to transmit the test images and corresponding information (e.g., the distribution of the probes 2421, the distance between the probes 2421 of the probe card 242 and the surface of the wafer W, the specification of the probes 2421 of the probe card 242, etc.,) of the test data to the database server 150.

The test method 400 proceeds to step 460, where the test data, the analyzed yield data, and the identification data are transmitted to an assessment subsystem. Referring to FIGS. 1 and 2, in some embodiments of the step 460, the test data, the analyzed yield data, and the identification data are transmitted to the assessment subsystem 130 in an automation mode. In other words, the assessment subsystem 130 is configured to receive the test data from the wafer test apparatus 110, the analyzed yield data, and the identification data from the optical check subsystem 140 in the automation mode. In some embodiments, the test method 400 further includes transmitting the test data, the analyzed yield data, and the identification data to the database server 150 in the automation mode.

The test method 400 proceeds to step 470, where an assessment operation is performed, by the assessment subsystem, on the test data, the analyzed yield data, and the identification data, to generate an assessment result. Referring to FIGS. 1-3, in some embodiments of the step 470, an assessment operation is performed, by the assessment subsystem 130, on the test data, the analyzed yield data, and the identification data, to generate an assessment result based on the test data, the analyzed yield data, and the identification data. In some embodiments, performing the assessment operation includes determining whether the test data, the analyzed yield data, and the identification data meet quality thresholds. In some embodiments, if all the test data, the analyzed yield data, and the identification data meet the quality thresholds, the assessment result indicates a pass result; if anyone of the test data, the analyzed yield data, and the identification data fails to meet the quality thresholds, the assessment result indicates a failure result.

In some embodiments, the assessment subsystem 130 is configured to respectively convert the test data, the analyzed yield data, and the identification data into a first value, a second value, and a third value. The assessment subsystem 130 is further configured to respectively compare the first value, the second value, and the third value with the quality thresholds to generate the assessment result.

In some embodiments, the assessment operation includes determining whether distances between the probe mark and the edges of the pad of the identification data meet a quality threshold. For example, as shown in FIGS. 1-3, when the distance Dx or Dy is within a certain range indicating that the probe mark overlaps with the edges of the pad and is spaced apart from the pad, the assessment subsystem 130 is configured to assess that the identification data meets the quality threshold, and thus the assessment result corresponding to the identification data indicates the pass result. In various embodiments, as shown in FIGS. 1-3, when the distance Dx or Dy is within a certain range indicating that the probe mark does not overlap with the edges of the pad or is in contact with the pad, the assessment subsystem 130 is configured to assess that the identification data fails to meet the quality threshold, and thus the assessment result corresponding to the identification data indicates the failure result.

In some embodiments, the test method 400 further includes capturing, by the process control processor 120, a portion of the test data, a portion of the analyzed yield data, and/or a portion of the identification data prior to performing the assessment operation. In some embodiments, the test method 400 further includes transmitting the assessment result to the database server 150 in response to a command sent by the process control processor 120.

The test method 400 proceeds to step 480, where a subsequent operation is performed based on the assessment result. Referring to FIGS. 1-3, in some embodiments of the step 480, the process control processor 120 is configured to perform a subsequent operation based on the assessment result. If the test data, the analyzed yield data, and the identification data meet the quality thresholds, the assessment subsystem 130 is configured to generate the assessment result indicating the pass result and the process control processor 120 is then configured to control the release subsystem 170 to perform a production process. In contrast, if anyone of the test data, the analyzed yield data, and the identification data fails to meet the quality thresholds, the assessment subsystem 130 is configured to generate the assessment result indicating the failure result and the process control processor 120 is then configured to perform a checking process. For example, the checking process includes at least one of the steps 430, 440, 450, 460, and 470.

In some embodiments, as shown in FIG. 1, the test method 400 further includes generating a process/product report by the assessment subsystem 130 based on the assessment result. The process/product report may be transmitted to the database server 150 or other subsystem/server for the supervisor operators to review.

It should be noted that the test system 10 depicted in FIG. 1 may also include a processing device for realizing one or more of the tools, subsystems, methods, or operations described with respect to FIG. 1 to FIG. 5.

In summary, since the test system includes the assessment subsystem, the optical check subsystem and the process control processor, the productivity and efficiency in testing a wafer can be enhanced. Further, manual effort and human errors can be avoided or reduced, thereby enhancing overall productivity of testing process.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A test system, comprising:
an assessment subsystem configured to:
receive a test data from a wafer test apparatus, wherein the test data comprises a test image of a wafer;
receive an analyzed yield data of the wafer; and
receive an identification data based on the test image;
an optical check subsystem; and
a process control processor configured:
in response to the wafer test apparatus to perform a test operation to generate the test data;
in response to the optical check subsystem to identify an image specification of probe marks in the test image and to generate the identification data; and
in response to the assessment subsystem to perform an assessment operation to generate an assessment result based on the test data, the analyzed yield data, and the identification data.

2. The test system of claim 1, wherein the process control processor is further configured to transmit the test data, the analyzed yield data, and the identification data to the assessment subsystem in an automation mode.

3. The test system of claim 1, wherein the process control processor is further configured to perform a verification operation on the wafer to generate the analyzed yield data.

4. The test system of claim 1, further comprising:
a database server connected to the process control processor and configured to save the test data, the analyzed yield data, and the identification data.

5. The test system of claim 4, wherein the database server is further connected to the assessment subsystem and configured to save the assessment result.

6. The test system of claim 1, further comprising:
a recipe server connected to the process control processor and configured to save a recipe data corresponding to the wafer test apparatus.

7. The test system of claim 1, wherein the image specification comprises coordinate of the probe marks, distances between the probe marks and edges of pads of the wafer, or a combination thereof.

8. The test system of claim 1, wherein the assessment operation comprises determining whether the test data, the analyzed yield data, and the identification data meet a plurality of quality thresholds.

9. The test system of claim 8, wherein if the test data, the analyzed yield data, and the identification data meet the quality thresholds, the assessment result indicates a pass result, and wherein if anyone of the test data, the analyzed yield data, and the identification data fails to meet the quality thresholds, the assessment result indicates a failure result.

10. The test system of claim 1, wherein the test data comprises a distribution of probes of a probe card of the wafer test apparatus, a distance between the probes of the probe card and a surface of the wafer, a specification of the probes of the probe card, or a combination thereof.

11. A test method, comprising:
performing, by a wafer test apparatus, a test operation to generate a test data, wherein the test data comprises a test image of a wafer;
performing a verification operation on the wafer to generate an analyzed yield data;
identifying an image specification of probe marks in the test image to generate an identification data based on the test image; and
performing, by an assessment subsystem, an assessment operation on the test data, the analyzed yield data, and the identification data to generate an assessment result.

12. The test method of claim 11, wherein performing the assessment operation comprises:
determining whether the test data, the analyzed yield data, and the identification data meet a plurality of quality thresholds.

13. The test method of claim 12, wherein if anyone of the test data, the analyzed yield data, and the identification data fails to meet the quality thresholds, the assessment result indicates a failure result.

14. The test method of claim 12, wherein if the test data, the analyzed yield data, and the identification data meet the quality thresholds, the assessment result indicates a pass result, and
wherein the test method further comprises performing a production process.

15. The test method of claim 11, wherein performing the verification operation on the wafer to generate the analyzed yield data comprises:
analyzing the test data to obtain a yield data; and
comparing the yield data and a predetermined yield data to generate the analyzed yield data.

16. The test method of claim 11, wherein performing the test operation comprises:
detecting a distribution of probes of a probe card;
detecting a distance between the probes of the probe card and a surface of the wafer; and
detecting a specification of the probes of the probe card.

17. The test method of claim 11, wherein the image specification of the probe marks in the test image comprises coordinate of the probe marks, distances between the probe marks and edges of pads of the wafer, or a combination thereof.

18. The test method of claim 11, further comprising:
obtaining a recipe data corresponding to the wafer test apparatus.

19. The test method of claim 18, wherein performing the test operation comprises:
heating a probe card of the wafer test apparatus based on the recipe data; and
performing a clean operation on probes of the probe card based on the recipe data.

20. The test method of claim 11, further comprising:
transmitting the test data, the analyzed yield data, and the identification data to the assessment subsystem.
